(19) United States
(12) Patent Application Publication
(10) Pub. No.: US 2022/0301914 A1
(43) Pub. Date: Sep. 22, 2022

(54) ELECTROSTATIC CHUCK FOR A PLASMA PROCESSING APPARATUS

(71) Applicant: Tokyo Electron Limited, Tokyo (JP)

(72) Inventor: Shingo KOIWA, Miyagi (JP)

(73) Assignee: Tokyo Electron Limited, Tokyo (JP)

(21) Appl. No.: 17/207,777

(22) Filed: Mar. 22, 2021

(51) Int. Cl. H01L 21/683; H01J 37/32

(52) U.S. Cl. CPC H01L 21/6833; H01J 37/32715; H01J 2237/2007

(57) ABSTRACT

An electrostatic chuck including a base, an electrostatic chuck plate, and a heat insulating sheet disposed between the base and the electrostatic chuck plate, wherein the heat insulating sheet includes at least one thermal buffer located in the heat insulating sheet.

### CROSS-REFERENCE TO RELATED APPLICATION

The present disclosure contains subject matter related to JP1993347352, filed in the Japanese Patent Office on Jun. 15, 1992, the entire contents of which being incorporated herein by reference.

### TECHNICAL FIELD

The present disclosure relates to semiconductor manufacturing equipment and is generally directed to a method and an apparatus for processing substrates. More particularly, the disclosure relates to an electrostatic chuck (ESC) provided in a plasma processing apparatus.

### BACKGROUND

Conventional ESCs that are operable at high temperatures of 200° C. or more include a ceramic chuck plate with a heater layer, and a polyimide (PI) sheet as a heat insulating sheet bonded to the lower surface of the ceramic chuck plate by thermocompression bonding. The lower surface of the PI sheet is bonded to the upper surface of an aluminum base with an adhesive. This structure provides a large temperature difference between the upper and lower surfaces of the PI sheet, thus allowing the chuck plate to be heated to higher temperatures while maintaining the adhesive under its heatproof temperature.

### SUMMARY

As recognized by the present inventor, when ESCs of a conventional structure are heated to 300° C. or higher temperatures to soften the PI sheet for compression bonding, the chuck plate with the compression-bonded PI sheet can warp, during cooling, by a substantial amount due to the chuck plate's thermal expansion coefficient differing greatly from that of the PI sheet. This may cause problems such as failures in attracting the wafer, lack of uniformity in the ESC's attractive forces, separation between the chuck plate and the PI sheet, and separation between the PI sheet and the base.

In view of the above-observations, an exemplary embodiment is disclosed in which an electrostatic chuck includes a base, an electrostatic chuck plate, and a heat insulating sheet disposed between the base and the electrostatic chuck plate, wherein the heat insulating sheet includes at least one thermal buffer located in the heat insulating sheet.

In another exemplary embodiment, a substrate processing apparatus includes a process chamber, and an electrostatic chuck. The electrostatic chuck includes a base, an electrostatic chuck plate, and a heat insulating sheet disposed between the base and the electrostatic chuck plate, wherein the heat insulating sheet includes at least one thermal buffer located in the heat insulating sheet.

In another exemplary embodiment, an electrostatic chuck includes a base, an electrostatic chuck plate that includes one or more heaters that heat a substrate, and a heat insulating sheet disposed between the base and the electrostatic chuck plate. The heat insulating sheet includes at least one thermal buffer, and the heat insulating sheet includes polyimide, an epoxy resin, or a polyetheretherketone (PEEK) resin, and the heat insulating sheet includes heat insulating sheet pieces separated by thermal buffer spaces.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings.

FIG. 1 is a diagram of an exemplary capacitively coupled plasma (CCP) system according to the present disclosure.

FIG. 2 illustrates a sectional view of an electrostatic chuck (ESC) according to an exemplary embodiment.

FIGS. 3A and 3B illustrate sectional views demonstrating warpage of a conventional ESC.

FIG. 4 illustrates a sectional view demonstrating a conventional ESC causing warpage to a substrate.

FIG. 5 is a graph illustrating an example of a result obtained from a simulation of warpage of the ESC.

FIG. 6 is a diagram illustrating exemplary external dimensions of the ESC and the heat insulating sheet used in the simulation of FIG. 5.

FIGS. 7A-7C are plan views illustrating exemplary heat insulating sheets.

FIG. 8 is a graph illustrating an example of a result obtained from a simulation of warpage of the ESC.

FIG. 9 is a diagram illustrating exemplary external dimensions of the ESC and heat insulating sheet used in the simulation of FIG. 8.

FIG. 10 is a plan view illustrating an exemplary heat insulating sheet.

FIG. 11 is a plan view illustrating an exemplary heat insulating sheet.

FIG. 12 is a plan view illustrating an exemplary heat insulating sheet.

FIGS. 13A-13F illustrate exemplary ways to divide up a heat insulating sheet.

FIG. 14A is a graph illustrating an exemplary temperature distribution on the surface of the ESC.

FIG. 14B is graph illustrating an example of a maximum value representing the maximum difference in the temperature of the surface of the ESC with respect to width D2 of the space in the heat insulating sheet.

FIG. 15 illustrates an exemplary sectional view of an ESC that illustrates distance D1 and width D2.

FIGS. 16A-16C are sectional views illustrating exemplary heat insulating sheets.

FIGS. 17A-17C are sectional views illustrating exemplary heat insulating sheets.

### DETAILED DESCRIPTION

The description set forth below in connection with the appended drawings is intended as a description of various embodiments of the disclosed subject matter and is not necessarily intended to represent the only embodiment(s). In certain instances, the description includes specific details for the purpose of providing an understanding of the disclosed subject matter. However, it will be apparent to those skilled in the art that embodiments may be practiced without these specific details. In some instances, well-known structures and components may be shown in block diagram form in order to avoid obscuring the concepts of the disclosed subject matter.

Reference throughout the specification to “one embodiment” or “an embodiment” means that a particular feature, structure, characteristic, operation, or function described in connection with an embodiment is included in at least one embodiment of the disclosed subject matter. Thus, any appearance of the phrases “in one embodiment” or “in an embodiment” in the specification is not necessarily referring to the same embodiment. Further, the particular features, structures, characteristics, operations, or functions may be combined in any suitable manner in one or more embodiments. Further, it is intended that embodiments of the disclosed subject matter can and do cover modifications and variations of the described embodiments.

It must be noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the disclosed subject matter to any particular orientation or configuration. Furthermore, terms such as “first,” “second,” “third,” etc., merely identify one of a number of portions, components, points of reference, operations and/or functions as described herein, and likewise do not necessarily limit embodiments of the disclosed subject matter to any particular configuration or orientation.

After identifying limitations with conventional ESC structures, the present inventor recognized the benefit of introducing a thermal buffer in a heat insulating sheet to reduce stress from compression bonding between a ESC plate (e.g., ceramic chuck plate) and a heat insulating sheet (e.g., a PI sheet) in an ESC.

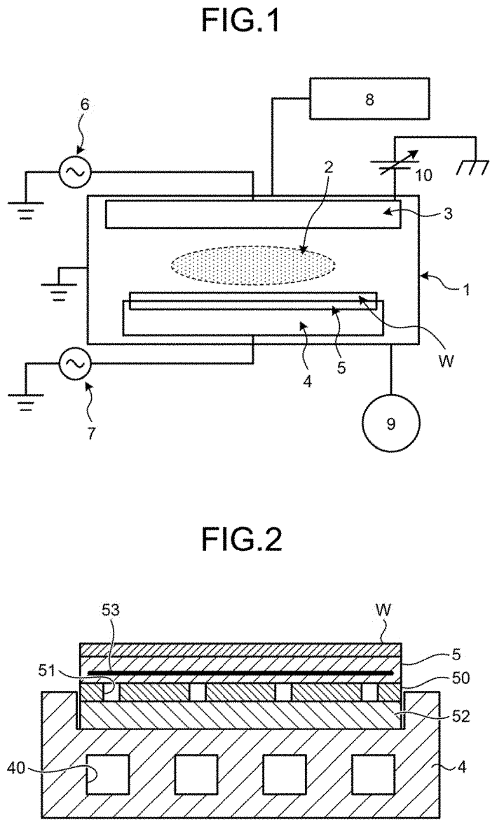

A configuration of a substrate processing apparatus, SA (e.g., a CCP type plasma system) according to an exemplary embodiment of the present disclosure will be described with reference to FIG. 1. The SA of FIG. 1 includes a chamber 1, an upper electrode 3, and a base 4 (e.g., a lower electrode). Radio Frequency, RF, power is coupled to the upper electrode 3 and the base 4 from RF sources 6 and 7. The power coupling may include differing RF frequencies. On the base 4, an ESC plate 5 is provided to support and retain a substrate W. In an exemplary embodiment, the ESC plate 5 is a structure having a flat surface, which, in this example, has a circular footprint. However, the ESC plate 5 can have any other geometric footprint such as, for example, elliptical, polygonal, oval, etc. as long as the upper surface is planar so it can serve as an electrostatic attraction structure that provides uniform electrostatic attraction to a substrate W. The ESC plate 5 includes a heater, as will be discussed in more detail with reference to FIG. 2. A gas source 8 is connected to the chamber 1 to supply one or more processing gases into the chamber 1. An exhaust device 9 such as a turbo molecular pump (TMP) is connected to the chamber 1 to evacuate the chamber 1. Plasma 2 is formed proximate to the substrate W between the upper electrode 3 and the base 4 as the RF power is supplied to at least one of the upper electrode 3 and the base 4. Alternatively, multiple RF power sources 6 and 7 may be coupled to the same electrode. Moreover, a variable (e.g., pulsed) direct current (DC) power source 10 may be coupled to the upper electrode 3.

FIG. 2 illustrates an enlarged sectional view of an ESC according to an exemplary embodiment. FIG. 2 illustrates an exemplary connection between the ESC plate 5 and a base 4, where in this embodiment the ESC plate 5 is provided on the base 4 via an adhesive 52 and a heat insulating sheet 50. That is, the heat insulating sheet 50 is located above the base 4 and the ESC plate 5 is located above the heat insulating sheet 50, such that the insulating sheet 50 is sandwiched between the ESC plate 5 and the adhesive 52 when the ESC is in the orientation shown in FIG. 2. In an exemplary embodiment, the heat insulating sheet 50 includes polyimide (PI), an epoxy resin, or a polyetheretherketone (PEEK) resin, and these various materials are sometimes referred to herein generically as a “PI sheet”. The insulating sheet 50 can include other materials or compounds. In an exemplary embodiment, the heat insulating sheet 50 can include a porous material. The ESC plate 5 includes one or more heaters (i.e., heating elements) 53.

The heat insulating sheet 50 includes one or more thermal buffers 51 (e.g., spaces 51 in the heat insulating sheet 50, or as will be discussed, spaces between pieces of the heat insulating sheet that collectively form the heat insulating sheet 50). In this context, the term “sheet” as used herein, should be construed as a single structure, or an arranged pattern of pieces separated by thermal buffers, that has a substantially uniform thickness, but need not be homogeneously uniform in cross-section because it includes one or more thermal buffers (e.g., gaps, voids, or spaces of varying sizes, patterns, and shapes) as will be discussed in much greater detail in the discussion of the respective embodiments. For example, in FIG. 2, the insulating sheet 50 includes four thermal buffers 51 as an example of one or more spaces (see, e.g., FIG. 2) that are located in a single insulating sheet 50 or between heat insulating sheet pieces (see, e.g., FIGS. 7A-7C, 10, 11, 12, 13C-13F) that collectively form an insulating sheet. These thermal buffers between insulating sheet pieces will be discussed in greater detail below.

The base 4 is provided with a channel 40 through which a temperature adjusting medium flows. An ESC with a structure with thermal buffers in the heat insulating sheet (for example, as in FIG. 2) has advantages in that it warps less than a conventional structure, and thus reliably results in increased flatness across the surface of the ESC. Consequently, as compared with conventional ESCs, the ESC embodiments described herein exhibit are less ESC failures in attracting the substrate (e.g., W), less separation between the ESC plate 5 and the heat insulating sheet 50, and less separation between the heat insulating sheet 50 and the base 4.

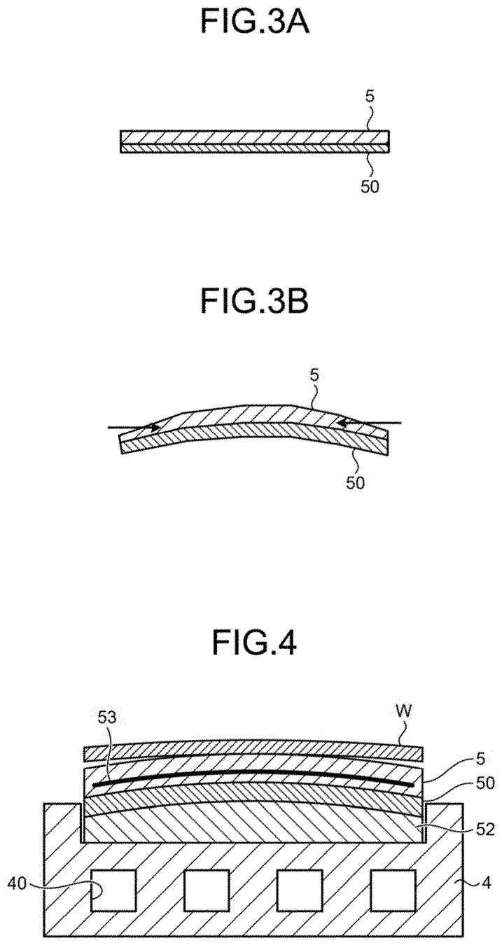

FIGS. 3A and 3B illustrate sectional views demonstrating warpage of a conventional ESC according to a comparative example. In this comparative example, the heat insulating sheet 50, which is not provided with a thermal buffer (e.g., space) 51, is thermo-compression bonded to the ESC plate 5, at a temperature of 300° C. or more, as illustrated in FIG. 3A. After the temperature of the heat insulating sheet 50 returns to room temperature, the ESC plate 5 with the compression-bonded heat insulating sheet 50 can warp greatly due to its thermal expansion coefficient differing greatly from that of the heat insulating sheet 50, as illustrated in FIG. 3B. Moreover, due to its adhesion to the ESC plate 5, the warping of the insulating sheet 50 gives rise to a warping of the ESC plate 5, thereby disturbing the desired planar surface of the ESC plate 5.

The effect of a non-planar surface of the ESC plate 5 is seen in the conventional ESC of FIG. 4, which illustrates a sectional view of a warped conventional ESC plate 5 that imparts uneven mechanical and electrostatic attractive forces across a bottom surface of the substrate W, which in turn causes undesired warpage of the substrate W.

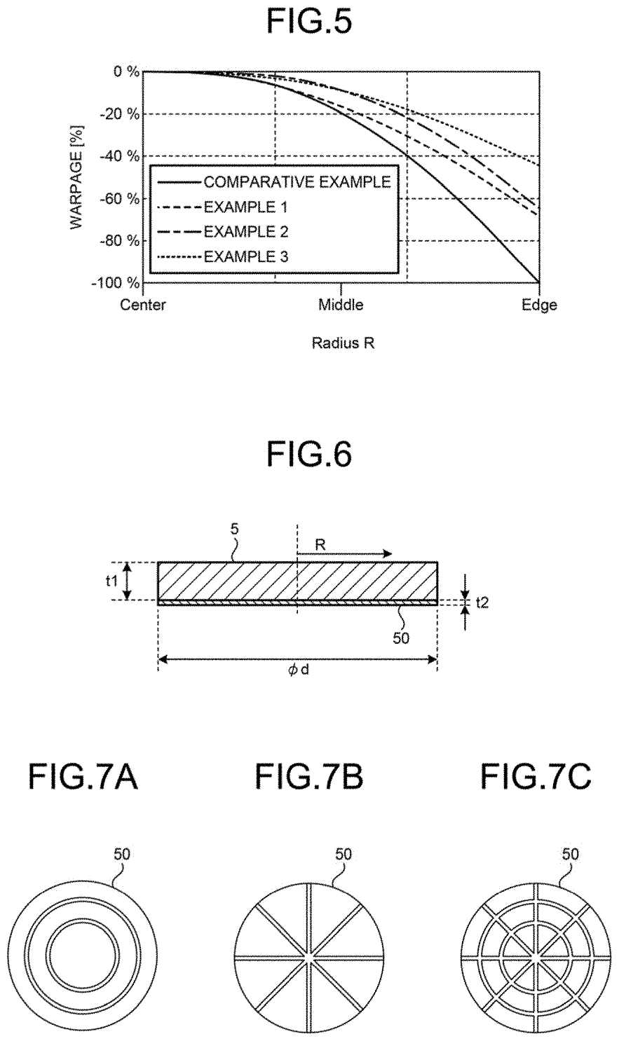

In reference to FIGS. 7A, 7B and 7C, the heat insulating sheet 50 includes a pattern of heat insulating sheet pieces, and the associated warpage characteristics of the ESC plate, as shown in FIG. 5, for respective of the sheets shown in FIGS. 7A, 7B, and 7C. Moreover, the graph of FIG. 5 illustrates results obtained from a simulation of warpage of the surface of the ESC vs. radius (as shown in FIG. 6) for four different configurations of the heat insulating sheet 50. In FIG. 5, the comparative example solid line is for a conventional ESC in which the heat insulating sheet 50 has no thermal buffers (i.e., the heat insulating sheet 50 is as shown in FIGS. 3A, 3B, and 4, and is devoid of buffers/gaps/spaces). In exemplary embodiments of the present disclosure, the heat insulating sheet 50 is divided annularly (as shown in FIG. 7A), radially (as shown in FIG. 7B), or both annularly and radially (as shown in FIG. 7C) so as to define a shape or patterns of shapes of the heat insulating sheet pieces, which collectively form the heat insulating sheet 50.

FIG. 5, shows the surface warpage of the ESC with a PI sheet as the heat insulating sheet 51 and a ceramic chuck plate bonded at 300° C. by thermocompression and then cooled to normal temperature (e.g., room temperature). The dashed line corresponding to example 1 is for the PI sheet being annularly cut (or two concentric annular buffers that define two annular pieces, and a center disc) as in FIG. 7A; the dashed line corresponding to example 2 is for the PI sheet being radially cut (or radially arranged thermal buffers that separate an pattern of eight wedge-shaped pieces) as in FIG. 7B; and the dashed line corresponding to example 3 is for the PI sheet being annularly and radially cut (i.e., a pattern of pieces resulting from a combination of pieces shown in FIGS. 7A and 7B) as in FIG. 7C. FIG. 6 illustrates the external dimensions of the ESC plate 5 and the PI sheet 50 used in the simulation to generate the results shown in FIG. 5. As seen in FIG. 6, the ESC plate 5 has thickness t1, the PI sheet has thickness t2 which is less than t1, and the ESC plate 5 and the PI sheet have a diameter d.

As seen in FIG. 5, warpage of the comparative example is 100 percent at a radius at the edge of the PI sheet, while warpage of example 1 is approximately 65 percent, warpage of example 2 is approximately 62 percent, and warpage of example 3 is approximately 45 percent. Thus, substantial reduction in warpage is achieved via segmentation of the heat insulating sheet 50 to include buffers (gap regions) in the sheet. Furthermore, as observed by the curves shown in FIG. 5, the number, shape, and pattern of thermal buffers in the heat insulating sheet 50 are variables that influence the amount of warpage suppression observed. Moreover, two annular buffer regions (FIG. 7A) exhibited less warpage suppression than that offered by radial buffers that segment the sheet into 8 pieces (FIG. 7B), which in turn was less than the composite pattern of FIG. 7C.

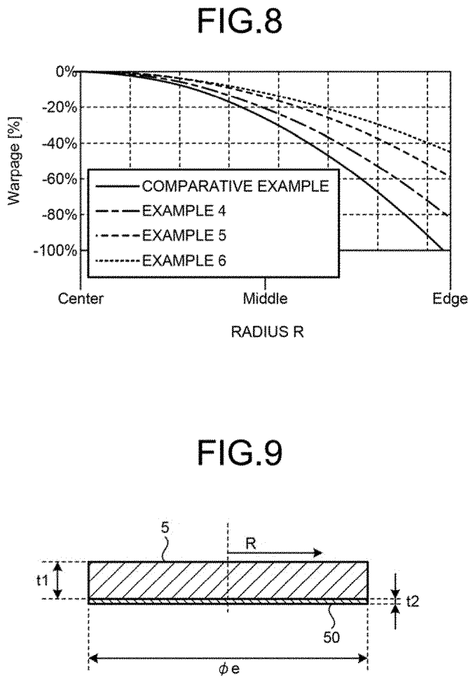

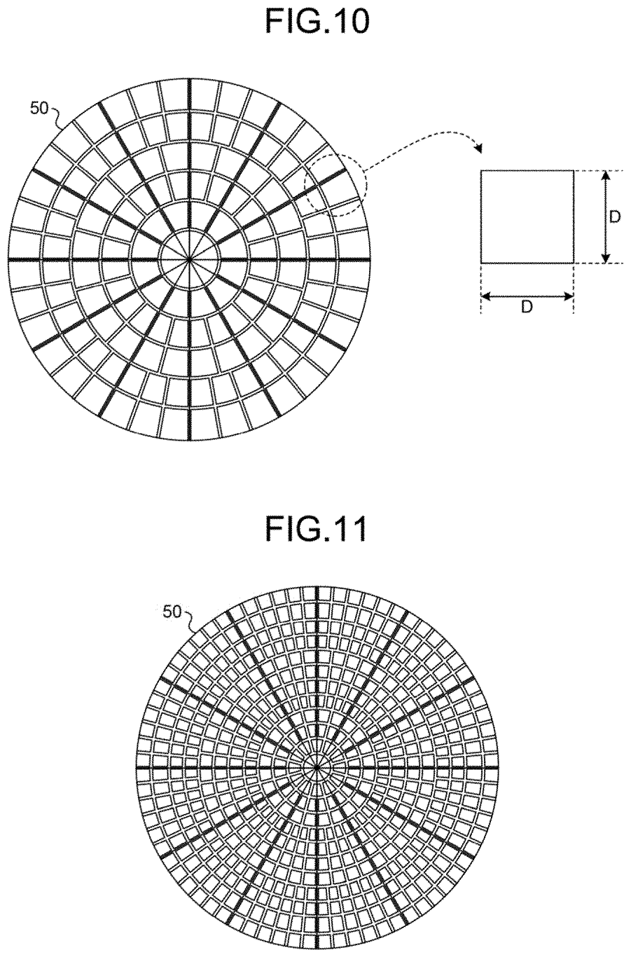

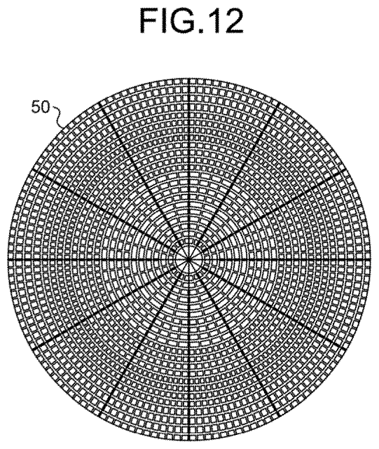

For heat insulating sheets with a larger surface area, dividing the heat insulating sheets into a greater number of pieces (heat insulating sheet pieces separated by thermal buffers) further reduces warping of the ESC plate 5 as seen in FIG. 8, which is a graph illustrating results obtained from a simulation of warpage of the ESC plate 5 for four different configurations of the PI sheet, a comparative example, and the examples of FIGS. 10, 11 and 12. In this simulation, the surface warpage of the ESC plate 5 is analyzed using a PI sheet and a ceramic chuck plate bonded at 300° C. by thermocompression bonding and then cooled to normal temperature. The comparative example solid line is for a conventional ESC in which the heat insulating sheet 50 is not cut or divided into different pieces (i.e., the heat insulating sheet 50 is as shown in FIGS. 3A, 3B, and 4). The dashed line corresponding to example 4 is for the PI sheet in FIG. 10 where a particular piece on the outer rim of the PI sheet has a widest dimension D (width or length). (It should be noted that the shape of each piece, as will be discussed, is actually an arcuate trapezoid, with straight sides, and arcuate outer and inner edges that match corresponding outer edge of the sheet 50, and inner edge of the buffer that separates the piece from the next, inner, piece.) The line corresponding to example 5 is for the PI sheet in FIG. 11 where the largest dimension D (width or length) of a piece on the outer rim of the PI sheet is less than the largest dimension D in FIG. 10 (e.g., less than half than the largest dimension D in FIG. 10, such as 45 percent of the largest dimension D in FIG. 10). The line corresponding to example 6 is for the PI sheet in FIG. 12 where the largest dimension D (width or length) of a piece on the outer rim of the PI sheet is less than one quarter of the largest dimension D in FIG. 10, such as 23 percent of the largest dimension D in FIG. 10). While the dimensions of the pieces of the outer rim of the PI sheet have a largest surface area of all of the pieces, there is not a requirement for these pieces to be the largest to provide the warpage suppression. The surface areas of other pieces, relative to the pieces on the outer rim, are typically not smaller than 20% as there is a tradeoff between number of buffer gaps and adhesive power of individual pieces. Thus, the ranges of surface areas of pieces relative to the largest pieces varies from 100% to 20%, although smaller pieces are possible, albeit with lower adhesive force.

As shown in FIG. 8, the warpage of the comparative example is approximately 100 percent at the edge, while the warpages of example 4 (where D is a largest one-sided dimension of a piece of PI sheet 50) is approximately 80 percent, example 5 (45 percent of the largest dimension D in FIG. 10) is approximately 60 percent, and example 6 (23 percent of the largest dimension D in FIG. 10) is approximately 40 percent. The respective pieces need not be square, and can have various shapes such as trapezoidal, with aspect ratios (height to width) of about 1.2 to 1.8, as will be discussed.

FIG. 9 illustrates the external dimensions of the ESC plate 5 and the PI sheet 50 used in the simulation of FIG. 8. As seen in FIG. 9, the ESC plate 5 has thickness t1, the PI sheet has thickness t2 which is less than t1, and the diameter φ of the ESC plate 5 and the PI sheet is e.

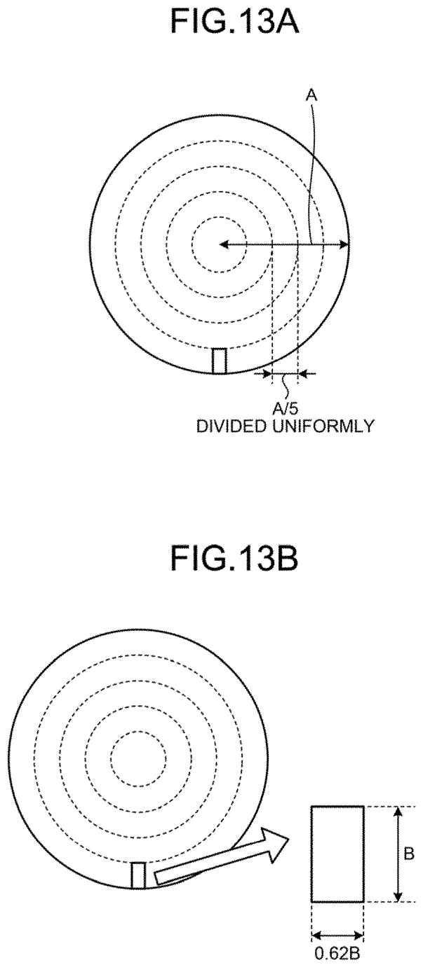

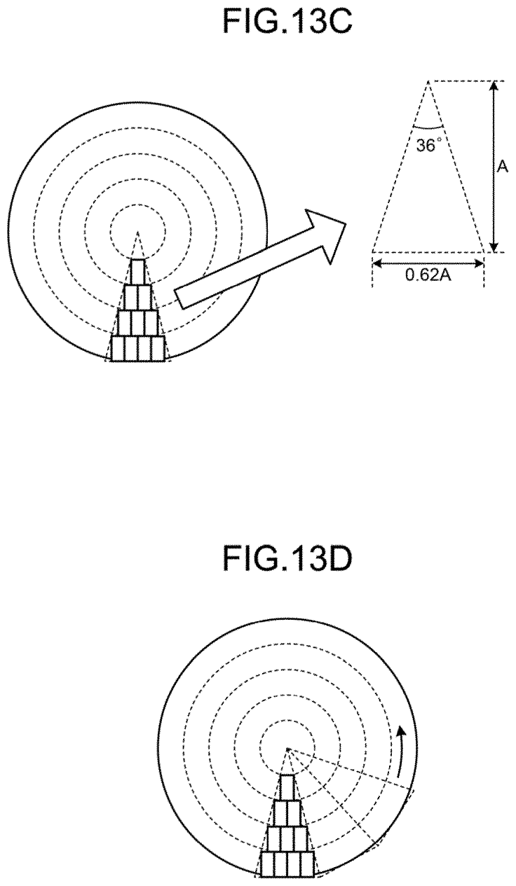

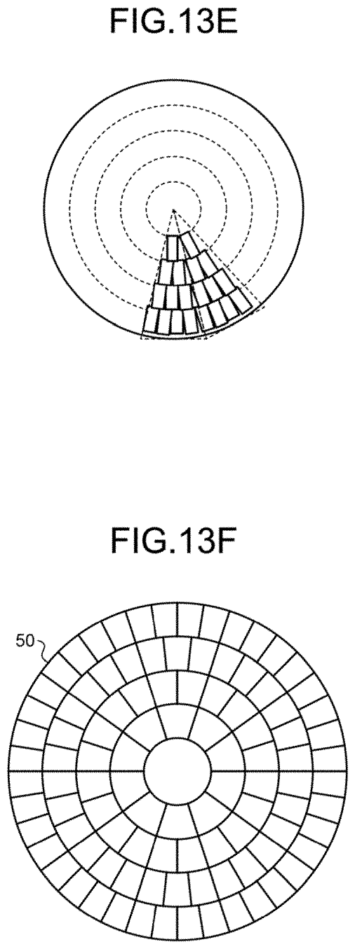

With regard to forming a pattern of pieces, heat insulating sheet pieces that each have an aspect ratio (height/width) of about 1.2 to 1.8 can be arranged uniformly across the heat insulating sheet. The heat insulating sheet pieces can be square, rectangular, trapezoidal (or arcuate trapezoidal as seen in FIG. 10), and other shapes as well, such as triangular (or pie shaped), like those at the center of FIG. 10. However, depending on the shape of the pieces, the size of the thermal buffers may be inconsistent. In an exemplary embodiment, the heat insulating sheet pieces are arcuate trapezoidal, and each heat insulating sheet piece has an aspect ratio of 1.2 to 1.8. With regard to the patterns shown in FIGS. 10, 11 and 12, each with pieces of differing sized arcuate trapezoidal shape. The arcuate trapezoidal shape has inner and outer edges that are curved to match segments of circumferences of outer and inner boundaries of the annular region, and straight sides that slope toward one another based on the annular span of each piece. Although this will be discussed more with respect to FIGS. 13A-13F, the pattern of pieces shown in FIG. 10 will be used as a present example.

In FIG. 10 the outermost ring includes arcuate trapezoidal shaped pieces with a largest dimension D spanning the outermost edge. The next row of pieces are arranged radially inward from the outermost ring of pieces and have a largest dimension on their outer edge that is shorter than the shortest dimension of the adjacent piece in the outmost ring. Thus, the two outermost rings have the same number of pieces in each ring, with the pieces in the outermost ring each having a larger surface area than those in the second ring. Notice that the third ring of pieces (as well as the fourth ring of pieces) are fewer in number (66%, or 2 pieces in the second ring for every three in the outer ring) of the pieces in the second ring, but the surface area of the pieces in the third ring are larger than that of the second ring. This allows for “pattern management” of the respective pieces that collectively form the PI sheet so that the dimensions of any of the pieces do not become so small that they provide an ineffective adhesive force, and too great a percentage of buffer area in the inner regions of the PI sheet. FIGS. 11 and 12 exhibit similar pattern management as that described above with respect to FIG. 10.

Although arcuate trapezoidal and pie-shaped pieces are shown in FIGS. 10-12 and have substantially uniform thermal buffer dimensions, other geometric shapes may be used as well, such as pentagonal, hexagonal, etc., where the respective pieces are arranged in a pattern to have variable width, but controlled (e.g., variation in buffer dimension of 20% or less) thermal buffers between them. Pieces with smooth shaped edges, such as circles, ovals, crescents and the like may be used as well, recognizing that the pattern of spacing of the pieces should be set such that a buffer separation between a large majority (90% or more) of pieces is a relatively small fraction (e.g., 10%, through 1%) of a longest feature (e.g., diameter) of the pieces. By establishing a balance between surface area of the respective pieces, shapes of the pieces, and placement of the pieces (e.g., the pattern arrangement of the pieces), the amount of warpage is managed within expected design parameters.

FIGS. 13A-13F illustrate an exemplary heat insulating sheet using “golden rectangles” as pieces. Golden rectangles can fill a circle substantially uniformly when satisfying a relationship between π and a golden ratio of sides of a rectangle of dimensions “a” and “b” (a/b=ϕ=1.61803 . . . ) namely π=(6/5)*ϕ².

In FIG. 13A, a disc-shaped PI sheet of radius A is shown, with the sheet divided into 5 concentric annular regions, each region having an A/5 width.

FIG. 13B illustrates a rectangular piece with dimensions that match that of a golden rectangle. Moreover, the longer side “a” of the rectangular piece has a dimension B (i.e., the width of each annular ring), and so the shorter side “b” is determined to have a dimension of 0.62 B according to a/b=ϕ=1.61803. Thus, the size of golden rectangles for the disc-shaped plate of FIG. 13A is 0.62 B×B.

Next, as shown in FIG. 13C, the disc-shaped plate has 10 equal-sized Isosceles triangles, each having a height of A, and center angle of 36°, which results in a base length of 0.62 A. As can be seen, 10 golden rectangles can be arranged in this Isosceles triangle, with the outer (5^{th}) annular sector containing 4 golden rectangles, the 4^{th} annular sector having 3, the 3^{rd} having 2, and the 2^{nd} having one. The innermost portion of the Isosceles triangle is a pie-shaped wedge, which itself is a mini-Isosceles triangle with height A/5 and center angle 36°.

FIG. 13D shows that 10 total Isosceles triangles are present in the disc-shaped plate. All 10 Isosceles triangles have the same arrangement as the Isosceles triangle shown in FIG. 13C.

FIG. 13E shows how a second Isosceles triangle contains golden rectangles, and naturally the remaining Isosceles triangles have the same arrangement.

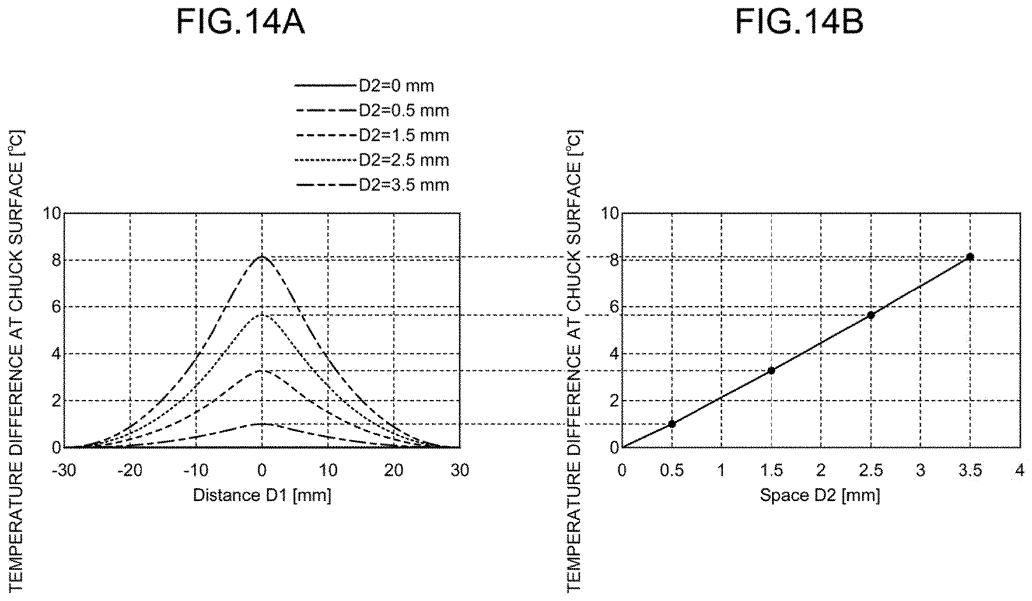

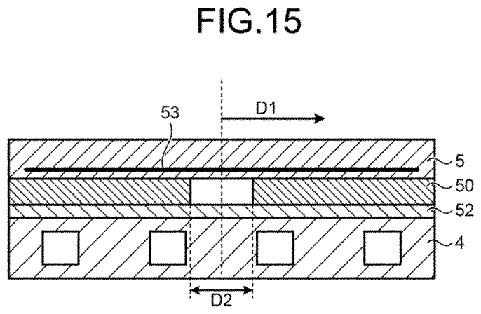

FIG. 13F illustrates how a piece-conversion of the respective golden rectangles into corresponding arcuate trapezoidal pieces. This piece conversation makes for uniformly sized thermal buffers (e.g., 0.5 mm) between each of the respective pieces. Moreover, each golden rectangle is converted to an arcuate trapezoidal shape, with inner and outer edges that match the shape of the inner and outer annular region in which they reside. However, the respective sides of the arcuate trapezoidal pieces are set to have a uniformly sized thermal buffer to a next piece. Likewise, a similar sized thermal buffer is set between the inner edge of a piece and an adjacent outermost edge of a piece that is resident in the next inner annular region. FIGS. 14A, 14B, and 15, will be discussed next regarding the effect of buffer distance between pieces affects temperature distribution.

FIGS. 14A and 14B are temperature distribution graphs that correspond with the structure shown in FIG. 15, where buffer distances, D2, are varied and the effect on temperature distribution is observed. FIG. 14A is a graph illustrating exemplary temperature distributions on the surface of the ESC at D1, varying distances from a center of the ESC (see FIG. 15), with 4 separate temperature/distance plots for each of 4 different buffer spaces D2 (see FIG. 15). FIG. 14B is graph illustrating an example of a maximum value representing the maximum difference in the temperature of the surface of the ESC with respect to width D2 in millimeters of the thermal buffer (space) 51 (FIG. 2) in the heat insulating sheet 50. In generating the result shown in FIGS. 14A and 14B, a voltage is applied to the heater 53, and the surface temperature of the ESC plate 5 is measured in both areas with the PI sheet, and buffer areas without the PI sheet. The temperature distribution is measured at the ESC surface in 0.5-mm wide blocks arranged laterally, simulating the division interval for vacuum insulation. In FIG. 14A, five lines are shown that correspond to different widths D2 of the thermal buffers (spaces). The five lines are for D2=0 mm, D2=0.5 mm, D2=1.5 mm, D2=2.5, and D2=3.5 mm. In FIG. 14A, a thermal buffer with 0.5 mm or less wide space has the flattest temperature difference (least variation). As seen in FIG. 14B, 1 mm or less wide spaces reduce the temperature difference to 2° C. or less, and 0.5 mm or less wide spaces reduce the temperature difference to 1° C. or less. Thus, the results show that larger buffer space results in greater variation in temperature difference and distribution, while smaller buffer space (e.g., 0.5 mm) results is less variation in temperature difference and distribution. In an exemplary embodiment, the one or more spaces 51 each have a width of 1 mm or less, such as 0.5 mm or less.

In an exemplary embodiment, the one or more thermal buffers 51 (e.g., spaces) are each decompressed or filled with a gas. FIG. 15 shows a space 51 according to an exemplary embodiment.

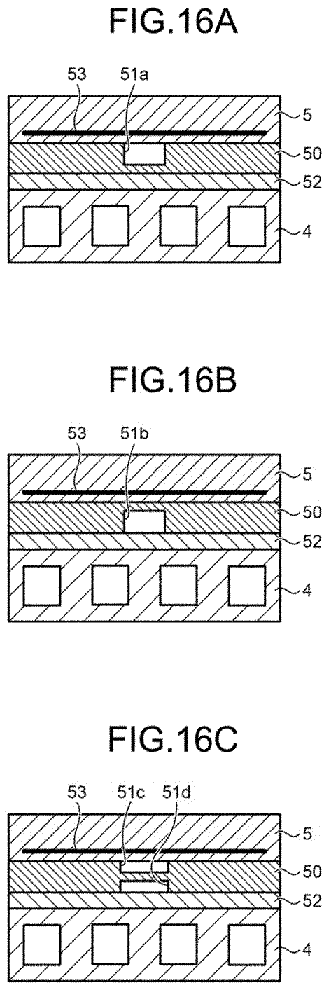

FIGS. 16A-16C are sectional views illustrating exemplary heat insulating sheets with different thermal buffer constructions, such as buffers 51a, 51b, 51c, and 51d. In an exemplary embodiment, the at least one thermal buffer (i.e., 51a, 51b, and 51c/51d) is one or more grooves in the heat insulating sheet 50. In FIG. 16A, the thermal buffer 51 is a bottomed groove 51a that is provided on the heat insulating sheet 50 facing the ESC plate 5. The bottomed groove 51a does not completely dissect the insulating sheet 50, and leaves a portion of the insulating sheet 50 intact under the groove 51a. In FIG. 16B, the bottomed groove 51b is provided on the heat insulating sheet 50 facing the base 4 and leaves a portion of the insulating sheet 50 intact over the groove 51a. In FIG. 16C, the bottomed groove 51c is provided on the heat insulating sheet 50 facing the ESC plate 5, and the bottomed groove 51d is provided on the heat insulating sheet 50 facing the base 4, and a residual portion of the insulating sheet 50 remains intact between grooves 51c and 51d.

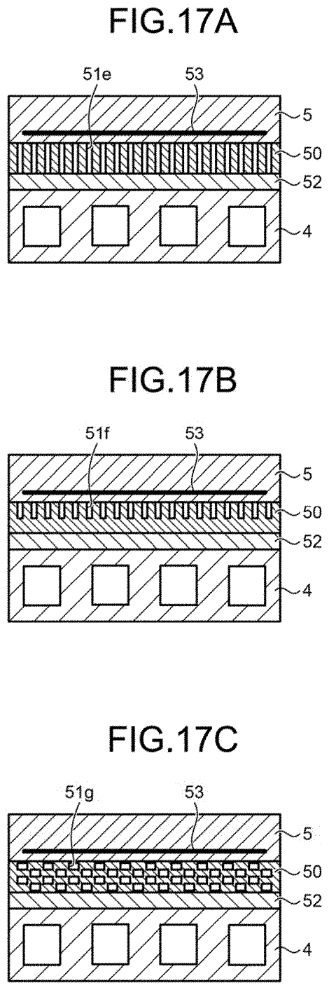

FIGS. 17A-17C are sectional views illustrating exemplary heat insulating sheets. In an exemplary embodiment, the at least one thermal buffer 51 is one or more holes in the heat insulating sheet 50. In an exemplary embodiment, the one or more holes are through-holes and/or recess holes. See FIG. 17A, in which a plurality of through holes 51e are formed in the heat insulating sheet 50. See FIG. 17B, in which a plurality of recess holes 51f are formed in the heat insulating sheet 50, but do not completely extend through an entirety of the heat insulating sheet 50. In an exemplary embodiment, the heat insulating sheet 50 includes a porous material. See FIG. 17C, in which a porous material having a plurality of pores 51g is provided as the heat insulating sheet 50.

Having now described embodiments of the disclosed subject matter, it should be apparent to those skilled in the art that the foregoing is merely illustrative and not limiting, having been presented by way of example only. Thus, although particular configurations have been discussed herein, other configurations can also be employed. Numerous modifications and other embodiments (e.g., combinations, rearrangements, etc.) are enabled by the present disclosure and are within the scope of one of ordinary skill in the art and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicant(s) intend(s) to embrace all such alternatives, modifications, equivalents, and variations that are within the spirit and scope of the disclosed subject matter.

### ELEMENT REFERENCE NUMERALS

D1 Distance
D2 Width
R Radius
W Wafer
1 Chamber
2 Plasma
3 Upper Electrode
4 Base/Lower Electrode
5 Electrostatic Chuck (ESC) Plate
6, 7 Radio Frequency (RF) Sources
8 Gas Source
9 Exhaust Device
10 Direct Current Source
40 Channel
50 Heat Insulating Sheet
51 Space
51a Bottomed Groove
51b Bottomed Groove
51f Recess Hole
51g Pore
52 Adhesive
53 Heater

1. An electrostatic chuck comprising:
a base;
an electrostatic chuck plate; and
a heat insulating sheet disposed between the base and the electrostatic chuck plate, wherein the heat insulating sheet includes at least one thermal buffer located in the heat insulating sheet.

2. The electrostatic chuck of claim 1, wherein
the heat insulating sheet includes heat insulating sheet pieces arranged in a predetermined pattern, and
the at least one thermal buffer includes a space that, from a plan perspective, separates adjacent heat insulating sheet pieces.

3. The electrostatic chuck of claim 2, wherein the at least one thermal buffer includes a plurality of thermal buffers that divide the heat insulating sheet annularly, radially, or both annularly and radially so as to define respective shapes of the heat insulating sheet pieces and the predetermined pattern.

4. The electrostatic chuck of claim 2, wherein the heat insulating sheet pieces includes shaped pieces that are rectangular, trapezoidal, or arcuate trapezoidal in shape.

5. The electrostatic chuck of claim 4, wherein the heat insulating sheet pieces are arcuate trapezoidal in shape with an aspect ratio in an inclusive range of 1.2 to 1.8.

6. The electrostatic chuck of claim 1, wherein the at least one thermal buffer includes one or more grooves in the heat insulating sheet.

7. The electrostatic chuck of claim 1, wherein the at least one thermal buffer includes one or more holes in the heat insulating sheet.

8. The electrostatic chuck of claim 7, wherein the one or more holes are through-holes and/or recess holes.

9. The electrostatic chuck of claim 1, wherein the heat insulating sheet includes a porous material.

10. The electrostatic chuck of claim 2, wherein the one or more spaces are each decompressed or filled with a gas.

11. The electrostatic chuck of claim 2, wherein the one or more spaces each have a width of 1 mm or less.

12. The electrostatic chuck of claim 1, wherein the heat insulating sheet includes polyimide, an epoxy resin, or a polyetheretherketone (PEEK) resin.

13. The electrostatic chuck of claim 1, wherein the electrostatic chuck plate includes one or more heaters for heating a substrate.

14. A substrate processing apparatus comprising:
a process chamber; and
and electrostatic chuck including
a base,
an electrostatic chuck plate, and
a heat insulating sheet disposed between the base and the electrostatic chuck plate, wherein the heat insulating sheet includes at least one thermal buffer located in the heat insulating sheet.

15. The substrate processing apparatus of claim 14, wherein the heat insulating sheet includes heat insulating sheet pieces arranged in a predetermined pattern, and the at least one thermal buffer includes a space that, from a plan perspective, separates adjacent heat insulating sheet pieces.

16. The substrate processing apparatus of claim 15, wherein the at least one thermal buffer includes a plurality of thermal buffers that divide the heat insulating sheet annularly, radially, or both annularly and radially so as to define respective shapes of the heat insulating sheet pieces and the predetermined pattern.

17. The substrate processing apparatus of claim 15, wherein the heat insulating sheet pieces includes shaped pieces that are rectangular, trapezoidal, or arcuate trapezoidal in shape.

18. The substrate processing apparatus of claim 17, wherein the heat insulating sheet pieces has arcuate trapezoidal in shape with an aspect ratio in an inclusive range of 1.2 to 1.8.

19. The substrate processing apparatus of claim 14, wherein the at least one thermal buffer includes one or more grooves in the heat insulating sheet.

20. An electrostatic chuck comprising:
a base;
an electrostatic chuck plate that includes one or more heaters that heat a substrate; and
a heat insulating sheet disposed between the base and the electrostatic chuck plate, wherein
the heat insulating sheet includes at least one thermal buffer, and the heat insulating sheet includes polyimide, an epoxy resin, or a polyetheretherketone (PEEK) resin, and
the heat insulating sheet includes heat insulating sheet pieces separated by thermal buffer spaces.
